(19) United States
(12) Patent Application Publication
(10) Pub. No.: US 2010/0177493 A1
(43) Pub. Date: Jul. 15, 2010

(54) Method for providing a protective film over a capacitor

(76) Inventors: Ming-Hsi Tsou, Taichung County (TW); Chia Pang Chen, Taichung County (TW); Chin-Chang Lin, Taichung County (TW)

Correspondence Address: CHARLES E. BAXLEY, ESQUIRE, 90 JOHN STREET, SUITE 309, NEW YORK, NY, 10038, US

(21) Appl. No.: 12/321,060

(22) Filed: Jan. 14, 2009

(51) Int. Cl. H05K 7/00; B05D 5/12

(52) U.S. Cl. 361/821; 427/79

(57) ABSTRACT

Disclosed is a method for providing a protective film over a capacitor. The method includes the steps of providing a capacitor with a first leg, a second leg and a shell, spraying paint onto the shell so that the thickness of the paint over the shell is even, and drying the paint so that the paint is turned into a protective film over the shell.

### FIELD OF INVENTION

The present invention relates to a capacitor and, more particularly, to a method for providing a protective film over a capacitor.

### BACKGROUND OF INVENTION

Referring to FIG. 1, a conventional capacitor 10 includes a first leg 11 and a second leg for connection to a positive electrode and a negative electrode, respectively. A shell is provided over the capacitor 10 and a protective film 15 is provided on the shell. The shell is made of aluminum. The protective film 15 is made of an isolating and airtight material. The protective film 15 is used for isolating and protecting the capacitor 10 from vapor. Moreover, a model number, specification and/or trademark can be printed on the protective film 15.

To form the protective film 15, there are several methods. In a first method, the capacitor 10 is provided with the shell before the protective film 15 is provided over the shell. The first method is inconvenient and slow. Furthermore, an upper portion of the shell is not covered with the protective film 15. The capacitor 10 is not adequately airtight, and vapor would penetrate the shell and reacts with conductive polymer within the shell. Thus, the capacity and life of the capacitor 10 would be compromised.

In a second method, the protective film 15 is paved on a sheet of aluminum before the sheet of aluminum is provided, as a shell, over the capacitor 10. The second method is expensive. The protective film 15 can easily be scratched during the wrapping of the capacitor 10 with the sheet of aluminum.

Referring to FIG. 2, in a third method, the capacitor 10 is made with the legs 11 and 12. Then, the legs 11 and 12 are held with the holder 25. The holder 25 is lowered so that the capacitor 10 is dipped in paint (marked with “A”) contained in a tank 20. The paint may be powder that is heated and hence melted before the dipping of the capacitor 10. Alternatively, the paint may simply be liquid. Finally, the paint over the capacitor 10 is dried and used as the protective film 15. However, the paint flows over the capacity 10 before the paint is completely dried. Therefore, the thickness of the protective film 15 is uneven. The look is ugly. Furthermore, the airtight performance of the protective film 15 is poor where it is too thin, and the heat radiation of the protective film 15 is poor where it is too thick. Either way, the performance and life of the capacitor 10 are jeopardized.

The present invention is therefore intended to obviate or at least alleviate the problems encountered in prior art.

### SUMMARY OF INVENTION

The primary objective of the present invention is to provide a method for providing a protective film over a capacitor so that the capacitor is low in cost but high in performance and long in life.

According to the present invention, the method includes the steps of providing a capacitor with a first leg, a second leg and a shell, spraying paint onto the shell so that the thickness of the paint over the shell is even, and drying the paint so that the paint is turned into a protective film over the shell.

Other objectives, advantages and features of the present invention will become apparent from the following description referring to the attached drawings.

### BRIEF DESCRIPTION OF DRAWINGS

The present invention will be described via detailed illustration of two embodiments versus the prior art referring to the drawings.

FIG. 1 is a front view of a typical capacitor.

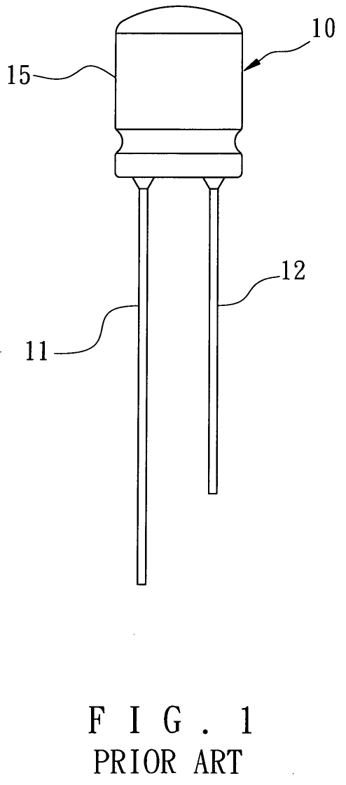

FIG. 2 is a cross-sectional view of a conventional apparatus for providing a protective film over the capacitor shown in FIG. 1.

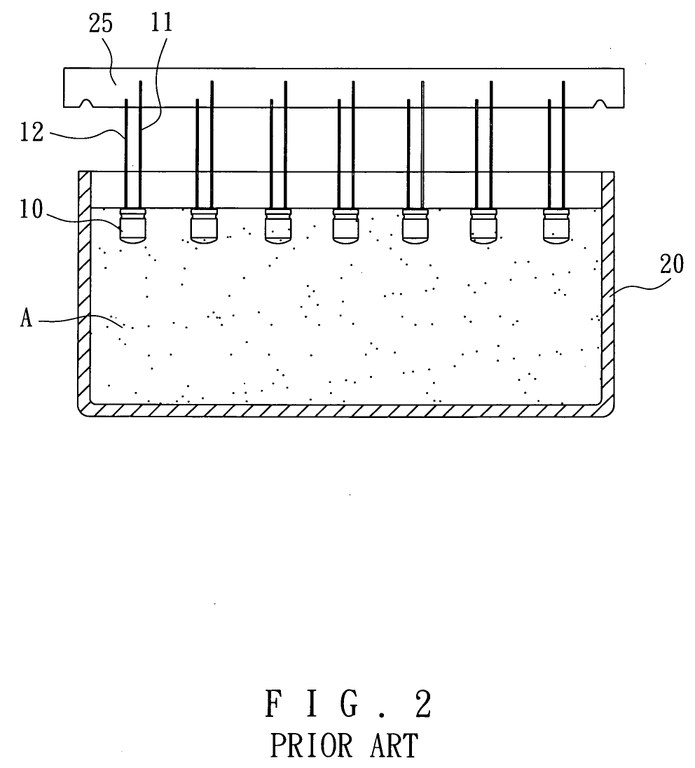

FIG. 3 is a flow chart of a method for providing a protective film over a capacitor according to the first embodiment of the present invention.

FIG. 4 is front view of an apparatus for executing the method shown in FIG. 1.

FIG. 5 is an enlarged, partial, cross-sectional view of a capacitor and the apparatus shown in FIG. 1.

FIG. 6 is top view of a sheet of aluminum and an apparatus for providing a protective film on the sheet of aluminum according to the second embodiment of the present invention.

FIG. 7 is a front view of a core of a capacitor to be wrapped with the sheet of aluminum shown in FIG. 6.

FIG. 8 is a cross-sectional view of the capacitor shown in FIG. 7.

### DETAILED DESCRIPTION OF EMBODIMENTS

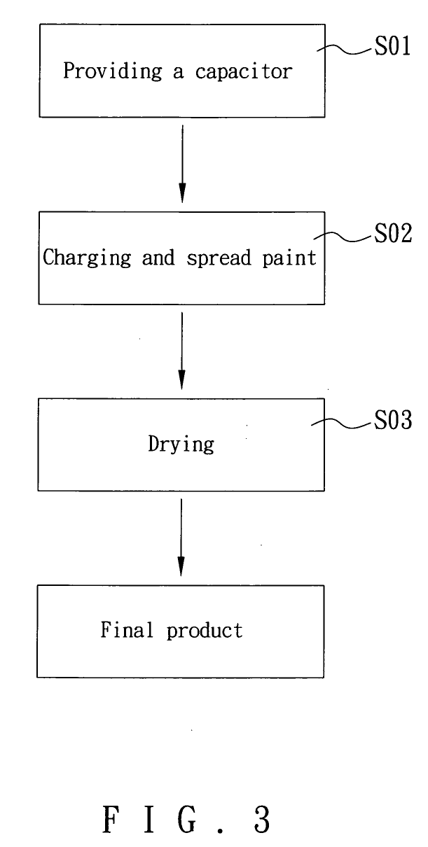

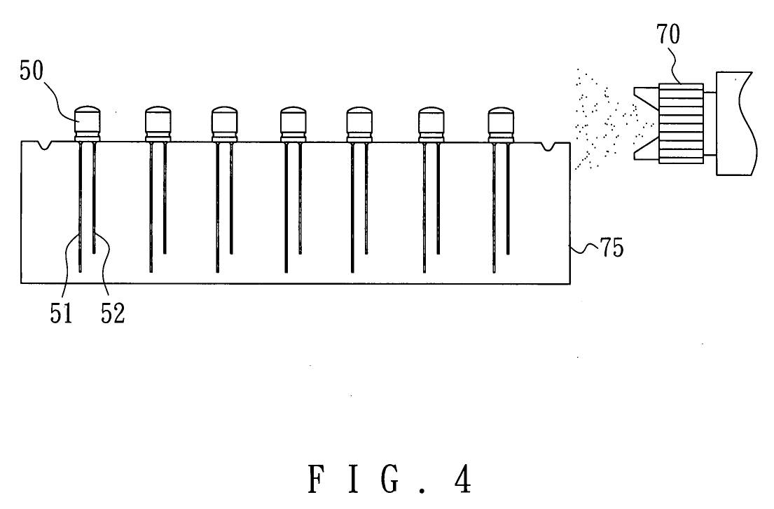

Referring to FIG. 3, there is shown a method for providing a protective film over a capacitor according to a first embodiment of the present invention. Referring to FIGS. 3 and 4, at S01, a capacitor 50 is provided a first leg 51, a second leg 52 and a shell 54.

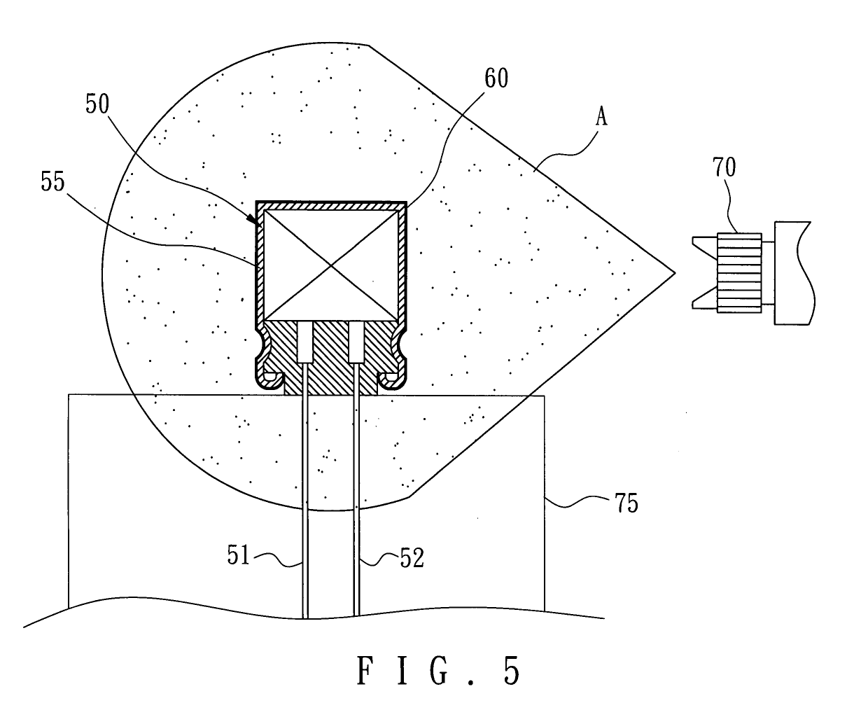

Referring to FIGS. 3 through 5, at S02, paint (indicated with “A”) is sprayed onto the shell 54. To this end, the legs 51 and 52 are completely inserted into a holder 75 before the paint is sprayed onto to the shell 54 from a nozzle 70. The shell 54 may be charged before the paint is sprayed thereto so that the consumption of the paint is low and the provision of the paint over the shell 54 is even.

At S03, the paint is dried and hence made a protective film 60 over the shell 54. The thickness of the protective film 60 is 0.02 to 0.2 mm to reach a balance between airtight performance and heat radiation.

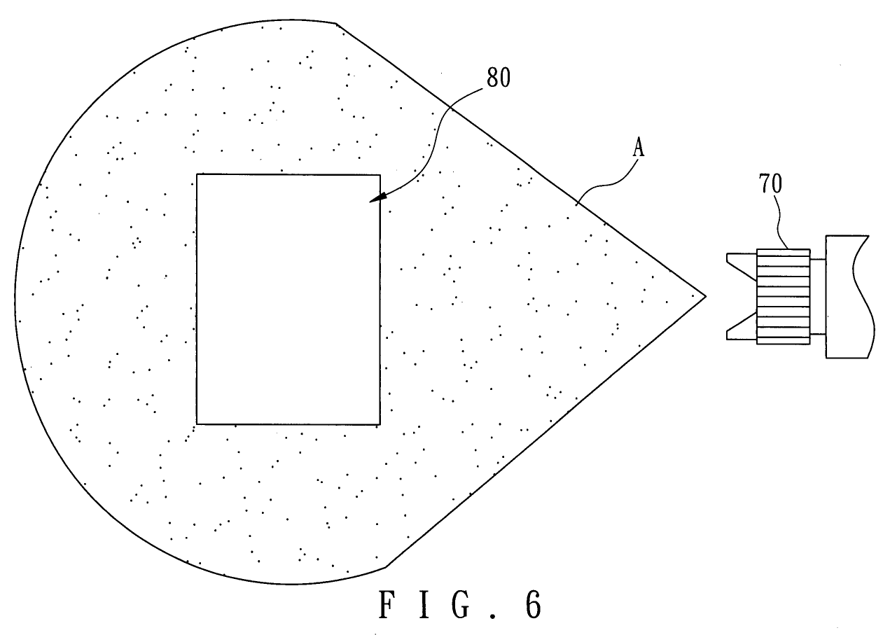

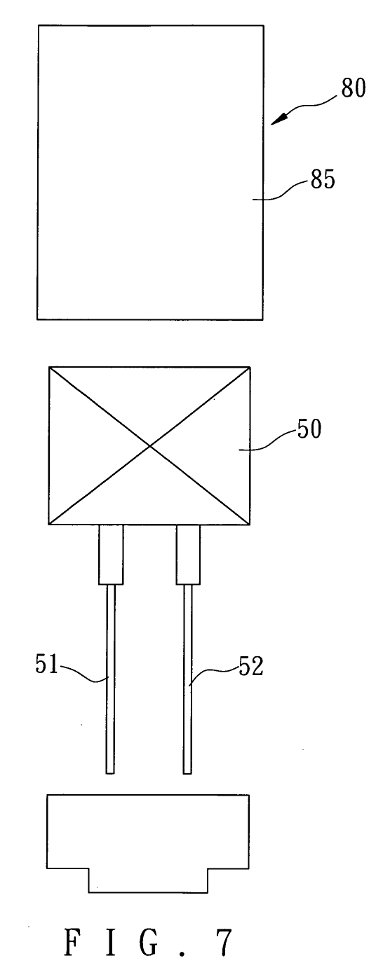

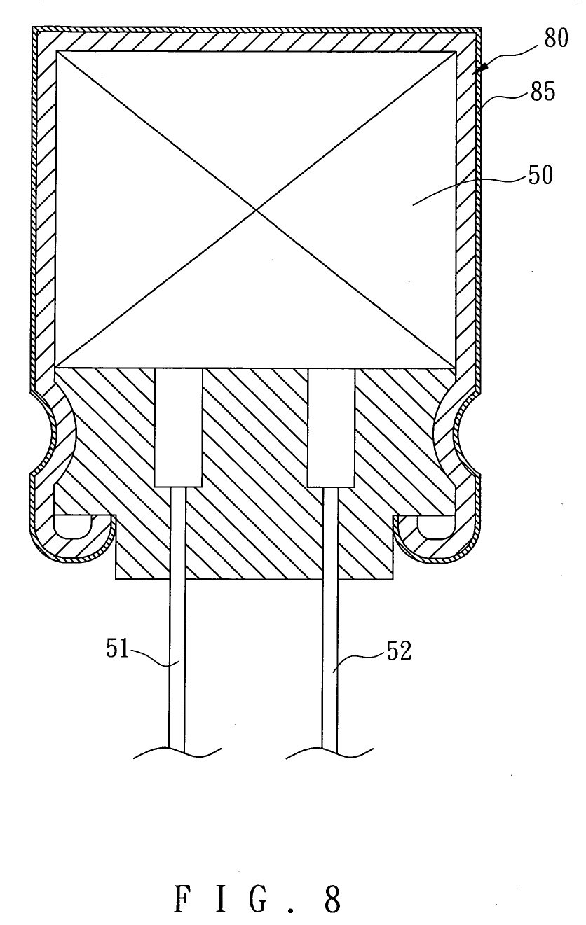

Referring to FIGS. 6 through 8, there is shown a method for providing a protective film on a capacitor according to a second embodiment of the present invention. At first, paint is sprayed onto a side of a sheet 80 of aluminum from a nozzle 70. The sheet 80 may be charged before the paint is sprayed thereto. Then, the paint is dried and made a protective film 85 over the sheet 80. Finally, the sheet 80 is provided over a capacitor 50. The sheet 80 is made a cylindrical shell for wrapping the capacitor 50.

The present invention has been described via the detailed illustration of the embodiments. Those skilled in the art can derive variations from the embodiments without departing from the scope of the present invention. Therefore, the embodiments shall not limit the scope of the present invention defined in the claims.

1. A method for providing a protective film over a capacitor comprising the steps of:
providing a capacitor with a first leg, a second leg and a shell;
spraying paint onto the shell so that the thickness of the paint over the shell is even; and
drying the paint so that the paint is turned into a protective film over the shell.

2. The method according to claim 1, wherein the step of spraying the paint onto the shell comprising the steps of:
providing a holder for holding the first and second legs of the capacitor; and
providing a nozzle for spraying the paint onto the shell.

3. The method according to claim 1, wherein the thickness of the protective film is 0.02 to 0.2 mm.

4. The method according to claim 1 comprising the step of charging the shell before the step of spraying the paint onto the shell.

5. A method for providing a protective film over a capacitor comprising the steps of:
providing a capacitor with a first leg and a second leg;
providing sheet;
spraying paint onto the sheet so that the thickness of the paint over the sheet is even;
drying the paint so that the paint is turned into a protective film over the sheet; and
wrapping the capacitor with the sheet so that the sheet is used as a shell over the capacitor.

6. A capacitor comprising:
two legs from an end thereof;
a shell thereon; and
a protective film over the shell, wherein the protective film is made of paint sprayed onto the shell.
